(19) United States
(12) Patent Application Publication
(10) Pub. No.: US 2024/0345149 A1
(43) Pub. Date: Oct. 17, 2024

(54) SPECTRAL INFORMATION SEPARATION AND AGGREGATION METHOD

(71) Applicants: North China Institute of Aerospace Engineering, Langfang (CN); Guangzhou University, Guangzhou (CN)

(72) Inventors: Yancang Wang, Langfang (CN); Guohong Li, Langfang (CN); Jinnian Wang, Langfang (CN); Yongtao Jin, Langfang (CN); Xuqing Li, Langfang (CN); Tianjiao Liu, Langfang (CN); Yan Zhang, Langfang (CN); Liang Zhang, Langfang (CN)

(21) Appl. No.: 18/361,823

(22) Filed: Jul. 29, 2023

Related U.S. Application Data
(63) Continuation of application No. PCT/CN2023/102721, filed on Jun. 27, 2023.

(30) Foreign Application Priority Data
Apr. 14, 2023 (CN) 2023104018107

(51) Int. Cl. G01R 29/26

(52) U.S. Cl. CPC G01R 29/26

(57) ABSTRACT

A spectral information separation and aggregation method includes: performing smooth denoising on spectral data through a spectral denoising method to obtain processed spectral data; processing the processed spectral data through a spectral data processing method to obtain spectral information with at least two dimensions and thereby spectral information of multi-dimensions are obtained; quantitatively analyzing correlations among spectral information of respective dimensions through a correlation-analysis algorithm, and calculating spectral information coupling coefficients according to the correlations among the spectral information of the respective dimensions; coupling the spectral information of multi-dimensions to thereby obtain resultant spectral information; and calculating a correlation between the resultant spectral information and ground-object parameters through a correlation-analysis algorithm, and evaluating an effect of the coupling. The method uses a hyperspectral technology to achieve effective aggregation of spectral data and couple available information within spectral data.

### TECHNICAL FIELD

The disclosure relates to the field of spectral data processing and separation technologies, and particularly to a spectral information separation and aggregation method.

### BACKGROUND

Remote sensing technology is a new non-destructive, accurate, real-time and fast information detection method, which has been widely used in detection of key indicators in county resources, land resources, environmental pollution, food safety, clothing quality and other fields, and will become a key technology of intelligent information in the future. With the continuous development of spectroscopy, a variety of new spectra have been discovered, different spectral analysis methods have been established, and corresponding spectral analysis instruments have emerged. Spectral analysis has been studied for a long time in principle and has become mature in theory. Spectral analysis method has become one of analytical methods with the most chemical means, the most widely used and the most powerful functions in modern analysis. The spectral analysis method has excellent performance in aspects of qualitative, quantitative and structural analysis, and has been applied to various fields such as soil information detection, life science, medical science, food, chemical industry, medicine, environment, commodity inspection, and space exploration. However, most of existing technologies for spectral data processing and analysis are shallow, while research and development on deep separation and aggregation of spectral data are relatively less.

In order to develop a spectral data separation and aggregation technology and provide a basic technical support for applications of the remote sensing technology in county remote sensing information detection and various industries, the disclosure breaks through the conventional thinking inertia, uses a spectral data separation and aggregation method as a breakthrough point, and develops a spectral information separation and aggregation method by means of a hyperspectral technology, thereby providing a new basic technical support for applications of the remote sensing technology in county remote sensing information and various fields of national economy.

### SUMMARY

A purpose of the disclosure is to provide a spectral information separation and aggregation method, which can achieve aggregation and separation of available information of spectral data, thereby effectively improving sensitivity of spectral information to detection indicators.

A detection principle of the disclosure may be as follows: available spectral information can be extracted from spectral data by using a spectral processing technology to process the spectral data, different processing methods can obtain different information contained in an original spectrum, and spectral information extracted based on a specific one of the processing methods can be regarded as an expression of the original spectrum in a certain dimension. When different methods are used to extract abundant information in the original spectrum, spectral information of multi-dimensions can be obtained consequently. If a correlation between spectral information of different dimensions is weak, there is a strong complementarity between the spectral information of different dimensions; therefore, it is important to couple the spectral information of different dimensions with weak correlations for improving the sensitivity of spectral information to ground-object parameters, which can provide a basic technical support for the application and promotion of spectral technology.

In order to achieve the above purpose, an embodiment of the disclosure provides the following technical solution.

Specifically, a spectral information separation and aggregation method, includes:
step a1, performing smooth denoising on spectral data through a spectral denoising method to obtain processed spectral data, to thereby improve a signal-to-noise ratio of the spectral data and weaken interferences of noise information on separation and aggregation of spectral information;
step b2, for the processed spectral data obtained in the step a1, processing the processed spectral data through a spectral data processing method to obtain spectral information of at least two dimensions and thereby spectral information of multi-dimensions are obtained, and recording the spectral information of multi-dimensions as SIₙ;
step c3, for the spectral information of multi-dimensions obtained in the step b2, quantitatively analyzing correlations among spectral information of respective dimensions through a correlation-analysis algorithm, and calculating spectral information coupling coefficients of the respective dimensions according to the correlations among the spectral information of the respective dimensions;
step d4, based on the spectral information coupling coefficients of the respective dimensions obtained in the step c3, coupling the spectral information of multi-dimensions obtained in the step b2 through a coupling technology to obtain resultant spectral information; and
step e5, calculating a correlation between the resultant spectral information obtained in the step d4 and ground-object parameters through a correlation-analysis algorithm, and evaluating an effect of the coupling.

In an embodiment, in the step a1, the spectral denoising method is used to perform smooth processing on the spectral data by a low-pass filter, and coefficients SM of the low-pass filter are as follows:

SM=[0.0800, 0.2147, 0.5400, 0.8653, 1.0000, 0.8653, 0.5400, 0.2147, 0.0800].

In an embodiment, in the step b2, the spectral data processing method is one of a traditional mathematical transformation, a wavelet transformation, and a spectral absorption feature algorithm.

In an embodiment, in the step c3, the correlation-analysis algorithm is as follows:

$$c o {r}_{j} = \frac{{Σ}_{i = 1}^{n} ( {X}_{i} - {X}_{A} ) * ( {Y}_{i} - {Y}_{A} )}{\sqrt{{Σ}_{i = 1}^{n} ( {X}_{i} - {X}_{A} )} * \sqrt{{Σ}_{i = 1}^{n} ( {Y}_{i} - {Y}_{A} )}}$$

where, corⱼ represents a correlation coefficient Xᵢ represents a spectral reflectance of an i-th sample in a waveband j, Yᵢ represents a measured parameter of the i-th sample, n represents a number of samples; X_{A} represents an average value of spectral reflectances of the samples in the waveband j, and Y_{A} represents an average value of the measured parameters of the respective samples in the wave band j;
moreover, a calculation method of the spectral information coupling coefficients is as follows:

$$c o {r}_{max \_ j} = max ( c o {r}_{j} )$$

$$co {r}_{max} = [ c o {r}_{max \_ 1} , co {r}_{max \_ 2} , … , {cor}_{max \_ n} ]$$

$$co {r}_{max \_ all} = max ( c o {r}_{max} )$$

$$coe {f}_{j} = \frac{c o {r}_{max \_ j}}{c o {r}_{max \_ all}}$$

where, cor_{max_j} represents one of a maximum correlation coefficient of a j-th transformation and a maximum correlation coefficient of a j-th scale based on wavelet decomposition; Corₘₐₓ represents a dataset constructed by the maximum correlation coefficients of respective transformations; Cor_{max_all} represents a maximum one of the maximum correlation coefficients of the respective transformations; coefⱼ represents a coupling coefficient of the j-th transformation; max represents solving a maximums value of a vector array.

In an embodiment, in the step d4, (a) or (b) as follows is carried out;
(a) when the coupling is performed on the spectral information of multi-dimensions obtained by the wavelet transformation, one of the following (1) and (2) is carried out;
   (1) after decomposition based on a same wavelet basis, a coupling formula of decomposed scale information is as follows:

$${S}_{c} = {\sum }_{n}^{1} S {W}_{j} * {coef}_{j}$$

where, S_{c} represents a coupling result of decomposed scale information after decomposition using the same wavelet basis, SW; represents decomposed j-th scale information, coefⱼ represents a coupling coefficient of the decomposed j-th scale information, and n represents a number of decomposition scales;
(2) after decomposition based on different wavelet bases, a coupling formula of decomposed scale information of each of the different wavelet bases is as follows:

$${S}_{wb \_ c} = {\sum }_{n}^{1} S {W}_{wb \_ j} * c o e {f}_{wb \_ m}$$

S_{wb_c} represents a coupling result of decomposed scale information after decomposition using a same wavelet basis wb of the different wavelet bases, SW_{wb_j} represents j-th scale information after decomposition using the wavelet basis wb, coef_{wb_j} represents a coupling coefficient of the j-th scale information after the decomposition using the wavelet basis wb, and n represents a number of decomposition scales,

$${S}_{c \_ all} = {\sum }_{m}^{1} S {W}_{wb \_ c} * c o e {f}_{wb \_ c}$$

where, S_{c_all} represents a coupling result of the different wavelet bases, SW_{wb_c} represents the coupling result of the decomposed scale information after decomposition using the wavelet basis wb, coef_{wb_c} represents a coupling coefficient of the coupling result of the decomposed scale information after decomposition using the wavelet basis wb, and m represents a number of the different wavelet bases;
(b) when the coupling is performed on the spectral information of multi-dimensions obtained by one of the traditional mathematical transformation and the spectral absorption feature algorithm, each of methods used for processing of spectral data is required to obtain spectral information of one dimension, namely, a data amount of the spectral data after being processed through each of the methods does not increase, and a formula is used as follows:

$${S}_{c} = {\sum }_{n}^{1} S {T}_{i} * c o e {f}_{i}$$

where, S_{c} represents a coupling result after processing of spectral data through the methods, STᵢ represents the spectral information obtained after processing of spectral data through an i-th method of the methods, coefᵢ represents a coupling coefficient of the spectral information obtained after processing of spectral data through the i-th method, and n represents a number of the methods.

In an embodiment, in the step e5, the evaluating an effect of the coupling includes:
performing preliminary evaluation on the effect of the coupling through a maximum value and an average value of correlation coefficients, and
performing a second evaluation on the effect of the coupling through maximum value and an average value of precision of an estimation model;
the maximum values reflect an optimal effect, and the average values reflect an overall effect.

In an embodiment, in the step e5, (x) or (y) as follows is carried out;
(x) for the coupling result of the spectral information obtained by the wavelet transformation, one of the following (1) and (2) is carried out;
   (1) for the coupling result obtained by decomposition based on the same wavelet basis and then coupling, using a same wavelet basis to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
   (2) for the coupling result obtained by decomposition based on the different wavelet bases, using the different wavelet bases to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
(y) for the coupling result of the spectral information processed by one of the traditional mathematical transformation and the spectral absorption feature algorithm, performing correlation-analysis directly with a detection object and performing evaluation using evaluation indicators, and;
the correlation-analysis algorithm used in the step e5 being as follows:

$$co {r}_{j} = \frac{{Σ}_{i = 1}^{n} ( {X}_{i} - {X}_{A} ) * ( {Y}_{i} - {Y}_{A} )}{\sqrt{{Σ}_{i = 1}^{n} ( {X}_{i} - {X}_{A} )} * \sqrt{{Σ}_{i = 1}^{n} ( {Y}_{i} - {Y}_{A} )}}$$

where, corⱼ represents a correlation coefficient Xᵢ represents a spectral reflectance of an i-th sample in a waveband j, Yᵢ represents a measured parameter of the i-th sample, n represents a number of samples; X_{A} represents an average value of spectral reflectances of the samples in the waveband j, and Y_{A} represents an average value of the measured parameters of the respective samples in the waveband j.

In an embodiment, a modeling method in the step e5 is one of random forest algorithm, neural network, and a partial least-square method.

The method according to the disclosure may have following beneficial effects.

Embodiments of the disclosure use a hyperspectral technology as a main means. The hyperspectral technology can achieve the aggregation and separation of available information within spectral data, can achieve effective aggregation of spectral data, and can improve the sensitivity and estimation ability of spectral data to a detection target/object, thereby providing a basic technical support for applications of spectral technology in various fields of the national economy. Moreover, the disclosure can have higher detection accuracy, better robustness and universality, and can effectively couple available information of spectrum.

### BRIEF DESCRIPTION OF DRA WINGS

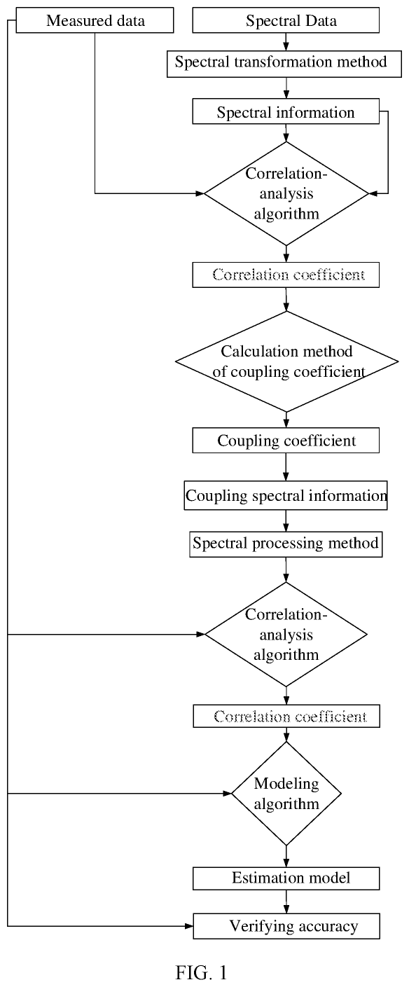

FIG. 1 illustrates a flowchart of a spectral information separation and aggregation method according to the disclosure.

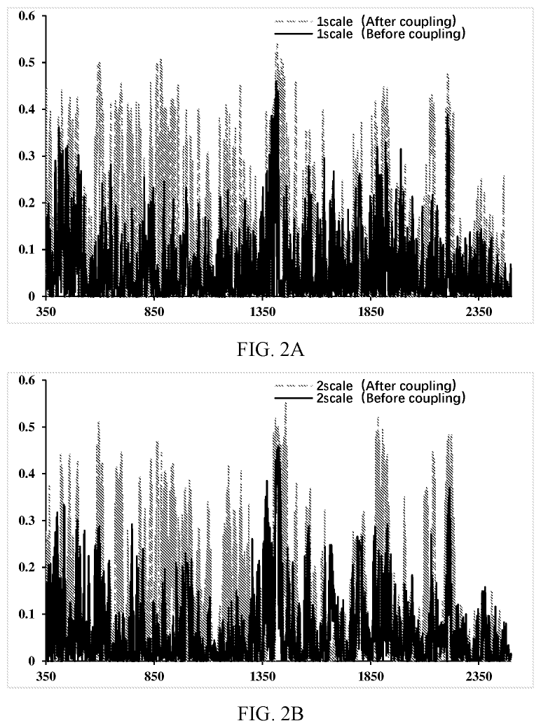

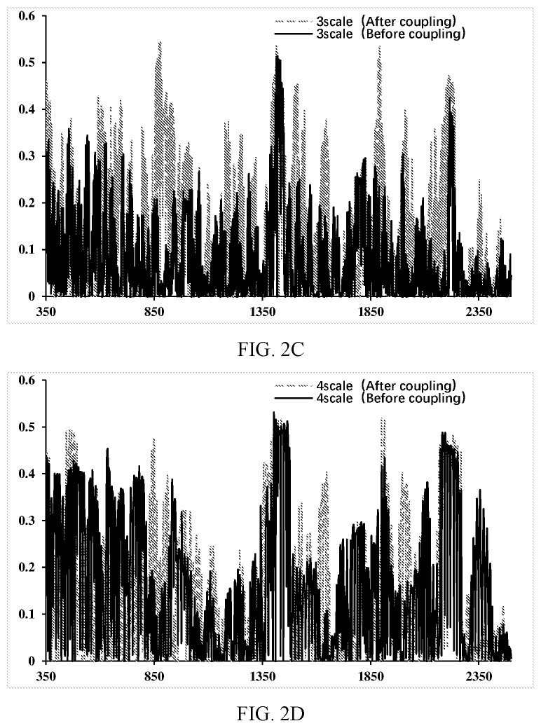

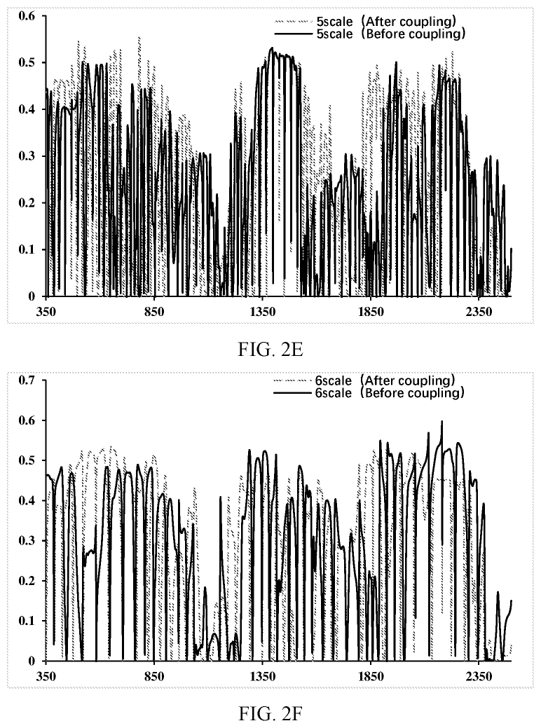

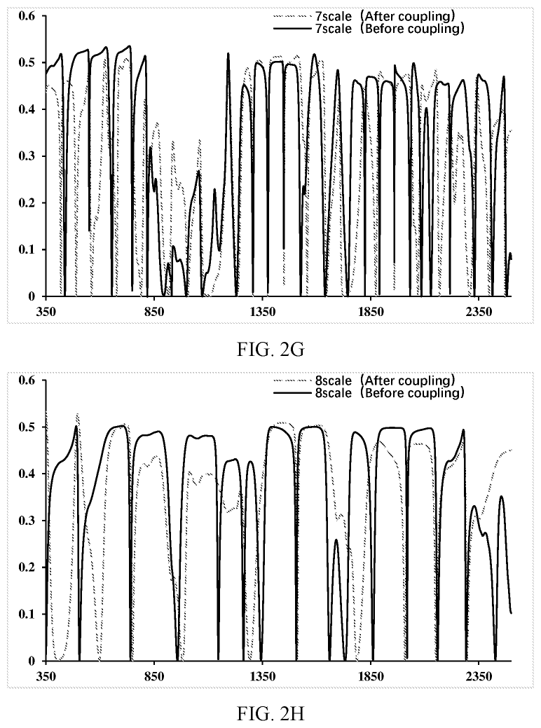

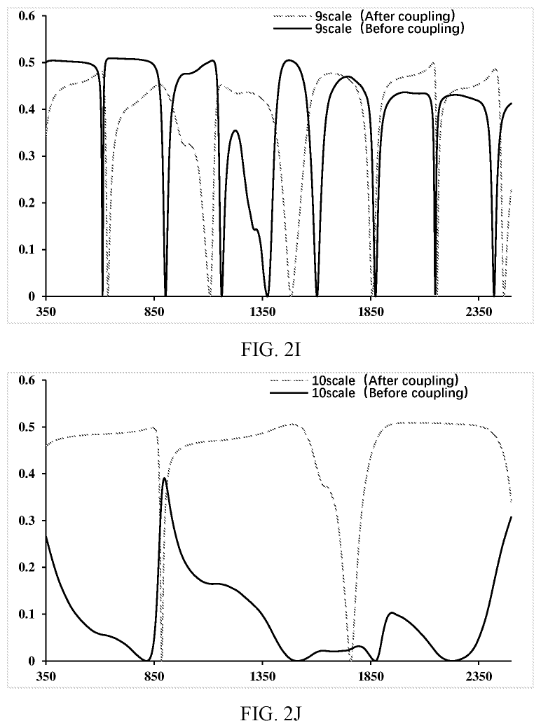

FIGS. 2A-2J illustrate comparison diagrams of correlation coefficients before and after coupling according to the disclosure.

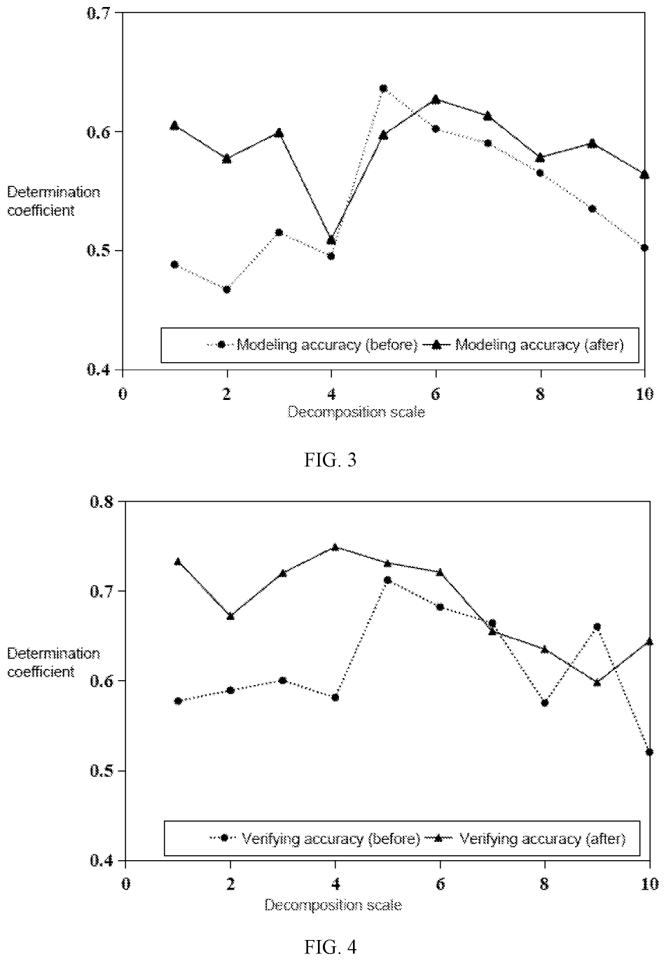

FIG. 3 illustrates a comparative analysis diagram of modeling accuracy of an estimation model before and after coupling according to the disclosure.

FIG. 4 illustrates a comparative analysis diagram of verification accuracy before and after coupling according to the disclosure.

### DETAILED DESCRIPTION OF EMBODIMENTS

The disclosure is further described below with reference to the attached drawings.

Specifically, a spectral information separation and aggregation method is shown in FIG. 1, and the spectral information separation and aggregation method includes:
step a1, performing smooth denoising on spectral data through a spectral denoising method to obtain processed spectral data, to thereby improve a signal-to-noise ratio of the spectral data and weaken interferences of noise information on separation and aggregation of spectral information;
step b2, for the processed spectral data obtained in the step a1, processing the processed spectral data through a spectral data processing method to obtain spectral information of at least two dimensions and thereby spectral information of multi-dimensions are obtained, and recording the spectral information of multi-dimensions as SIₙ;
step c3, for the spectral information of multi-dimensions obtained in the step b2, quantitatively analyzing correlations among spectral information of respective dimensions through a correlation-analysis algorithm, and calculating spectral information coupling coefficients of the respective dimensions according to the correlations among the spectral information of the respective dimensions;
step d4, based on the spectral information coupling coefficients of the respective dimensions obtained in the step c3, coupling the spectral information of multi-dimensions obtained in the step b2 through a coupling technology to obtain resultant spectral information; and
step e5, calculating a correlation between the resultant spectral information obtained in the step d4 and ground-object parameters through a correlation-analysis algorithm, and evaluating an effect of the coupling.

In an embodiment, in the step a1, the spectral denoising method is used to perform smooth processing on the spectral data by a low-pass filter, and coefficients SM of the low-pass filter are as follows:

$$SM = [ 0.08 , 0.2147 , 0.54 , \\ 0.8653 , 1. , 0.8653 , 0.54 , 0.2147 , 0.08 ] .$$

A corn sample is taken as an example, a specific calculation formula is as follows:
a spectrum of the corn sample is a function ƒ(x) of wavelength, ƒs(x) represents a spectrum after smooth processing, and i represents a wavelength, then:

$${f}_{s} ( x ) = \frac{{\sum }_{x - 4}^{x + 4} {f}_{s} ( i ) * S M [ i ]}{4.4}$$

In some embodiments, the spectral data processing method in the step b2 is one of a traditional mathematical transformation, a wavelet transformation, and a spectral absorption feature algorithm. In particular, the traditional mathematical transformation may use one of transformations such as logarithmic transformation, differential transformation, and deviation of arch. The wavelet transformation may be a continuous wavelet transformation, a discrete wavelet transformation, or a complex wavelet transformation, and so on. The spectral absorption feature algorithm may use algorithms such as envelope removal and absorption peak depth. An illustrated embodiment of the disclosure takes the discrete wavelet transformation as an example, which uses Coif2, db5, meyer, rbio3.7, and sym2 as wavelet bases, with a number of decomposition scales of 10 (in other word, 10 decomposition scales represent 10 dimensions). Decomposed spectral information based on the discrete wavelet transformation algorithm is marked as SW_{wb_n}, wb represents one of wavelet bases used in the formula, and n represents the decomposition scale (for example, SW_{db5_1} represents spectral information of 1 scale based on db5 wavelet basis).

Discrete wavelet algorithm: the discrete wavelet algorithm is a novel technique for signal processing, has the functions of multi-scale analysis and singular point detection, and can decompose signals into a series of high-frequency and low-frequency signals by using low-pass and high-pass filters. Specifically, a spectral resolution of low-frequency information decreases exponentially with the increase of decomposition times, and an embodiment of the disclosure mainly uses the low-frequency information of discrete wavelet. A formula of the discrete wavelet algorithm is as follows:

$${W}_{f} ( a , b ) = \frac{1}{\sqrt{{2}^{j}}} {\int }_{- ∞}^{+ ∞} f ( λ ) φ ( λ ) * \frac{λ - {2}^{j} k}{{2}^{j}} d λ$$

in this formula, ƒ(λ) represents one of spectral data and information processed by a spectral processing technology, parameter a represents a scale coefficient, which is the reciprocal of frequency; parameter b represents time shift (or translation), λ represents a wavelength, and φ(λ) represents a mother wavelet.

In order to obtain correlation coefficients and coupling coefficients, the correlation-analysis algorithm in the step c3 is as follows:

$${cor}_{j} = \frac{{\sum }_{i = 1}^{n} ( {X}_{i} - {X}_{A} ) * ( {Y}_{i} - {Y}_{A} )}{\sqrt{{\sum }_{i = 1}^{n} ( {X}_{i} - {X}_{A} )} * \sqrt{{\sum }_{i = 1}^{n} ( {Y}_{i} - {Y}_{A} )}}$$

where, corⱼ represents a correlation coefficient Xᵢ represents a spectral reflectance of an i-th sample in a waveband j, Yᵢ represents a measured parameter of the i-th sample, n represents a number of samples; X_{A} represents an average value of spectral reflectances of the samples in the waveband j, Y_{A} represents an average value of the measured parameters of the respective samples in the waveband j.

Moreover, a calculation method of the spectral information coupling coefficient is as follows:

$${cor}_{max \_ j} = max ( {cor}_{j} ) \\ {cor}_{max} = [ {cor}_{max \_ 1} , {cor}_{max \_ 2} , … , {cor}_{max \_ n} ] \\ {cor}_{max \_ all} = max ( {cor}_{max} ) \\ {coef}_{j} = \frac{{cor}_{max \_ j}}{{cor}_{max \_ all}}$$

where, cor_{max_j} represents one of a maximum correlation coefficient of a j-th transformation and a maximum correlation coefficient of a j-th scale based on wavelet decomposition; Corₘₐₓ represents a dataset constructed by the maximum correlation coefficients of respective transformations; Cor_{max_all} represents a maximum one of the maximum correlation coefficients of the respective transformations; coefⱼ represents a coupling coefficient of the j-th transformation; max represents solving a maximum value of a vector array.

In actual calculations of the correlation coefficients and the coupling coefficients in the step c3, MATLAB, C, C++, or other language can be used for programming to achieve the actual calculations of the correlation coefficients and the coupling coefficients.

In an embodiment, in the step d4, (a) or (b) as follows may be carried out.
(a) when the spectral data obtained by the wavelet transformation is coupled, the following (1) or (2) is carried out;
   (1) after decomposition based on a same wavelet basis, a coupling formula of decomposed scale information is as follows:

$${S}_{c} = {\sum }_{n}^{1} {SW}_{j} * {coef}_{j}$$

where, S_{c} represents a coupling result of decomposed scale information after decomposition using the same wavelet basis, SW; represents decomposed j-th scale information, coefⱼ represents a coupling coefficient of the decomposed j-th scale information, and n represents a number of decomposition scales;
(2) after decomposition based on different wavelet bases, a coupling formula of decomposed scale information of each of the different wavelet bases is as follows:

$${S}_{wb \_ c} = {\sum }_{n}^{1} {SW}_{wb \_j} * {coef}_{wb \_j}$$

where, S_{wb_c} represents a coupling result of decomposed scale information after decomposition using a same wavelet basis wb of the different wavelet bases, SW_{wb_j} represents j-th scale information after decomposition using the wavelet basis wb, coef_{wb_j} represents a coupling coefficient of the j-th scale information after the decomposition using the wavelet basis wb, and n represents a number of decomposition scales;

$${S}_{c \_ all} = {\sum }_{m}^{1} {SW}_{wb \_ c} * {coef}_{wb \_ c}$$

where, S_{c_all} represents a coupling result of the different wavelet bases, SW_{wb_c} represents the coupling result of the decomposed scale information after decomposition using the wavelet basis wb, coef_{wb_c} represents a coupling coefficient of the coupling result of the decomposed scale information after decomposition using the wavelet basis wb, and m represents a number of the different wavelet bases;
(b) when the coupling is performed on the spectral information of multi-dimensions obtained by one of the traditional mathematical transformation and the spectral absorption feature algorithm, each of methods used for processing of spectral data is required to obtain spectral information of one dimension, namely, a data amount of the spectral data after being processed through each of the methods does not increase, and a formula is used as follows:

$${S}_{c} = {\sum }_{n}^{1} {ST}_{i} * {coef}_{i}$$

where, S_{c} represents a coupling result after processing of spectral data through the methods, ST; represents the spectral information obtained after processing of spectral data through an i-th method of the methods, coefᵢ represents a coupling coefficient of the spectral information obtained after processing of spectral data through the i-th method, and n represents a number of the methods.

In a special case, each of the coupling coefficients can be considered as 1, but the effect of the coupling is limited, and a following formula can be used for the coupling:

$${S}_{wb \_ c} = {\sum }_{n}^{1} {SW}_{wb \_ j} * {coef}_{wb \_ j} \\ {S}_{c \_ all} = {\sum }_{n}^{1} {SW}_{wb \_ c}$$

where, S_{wb_c} represents a coupling result of decomposed scale information after decomposition using a same wavelet basis wb of the different wavelet bases; SW_{wb_j} represents j-th scale information after decomposition using the wavelet basis wb; and coef_{wb_j} represents a coupling coefficient of the j-th scale information after the decomposition using the wavelet basis wb.

Herein, the special case refers to a case that a fast calculation is needed, a case that a correlation between spectral information of different dimensions is relatively weaker, or a case that there is a strong complementarity between spectral information of different dimensions, and is determined according to actual needs.

In an embodiment of the disclosure, in the step e5, the evaluating an effect of the coupling includes:
performing preliminary evaluation on the effect of the coupling through a maximum value and an average value of correlation coefficients, and
performing a second evaluation on the effect of the coupling through maximum value and an average value of precision of an estimation model;
the maximum values reflect an optimal effect, and the average values reflect an overall effect.

In an embodiment, in the step e5, (x) or (y) as follows may be carried out;
(x) for the coupling result of the spectral information obtained by the wavelet transformation, one of the following (1) and (2) is carried out;
   (1) for the coupling result obtained by decomposition based on the same wavelet basis and then coupling, using a same wavelet basis to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
   (2) for the coupling result obtained by decomposition based on the different wavelet bases, using the different wavelet bases to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
(y) for the coupling result of the spectral information processed by one of the traditional mathematical transformation and the spectral absorption feature algorithm, performing correlation-analysis directly with a detection object and performing evaluation using evaluation indicators, and the correlation-analysis algorithm used in the step e5 being as follows:

$${cor}_{j} = \frac{{\sum }_{i = 1}^{n} ( {X}_{i} - {X}_{A} ) * ( {Y}_{i} - {Y}_{A} )}{\sqrt{{\sum }_{i = 1}^{n} ( {X}_{i} - {X}_{A} )} * \sqrt{{\sum }_{i = 1}^{n} ( {Y}_{i} - {Y}_{A} )}}$$

where, corⱼ represents a correlation coefficient, Xᵢ represents a spectral reflectance of an i-th sample in a waveband j, Yᵢ represents a measured parameter of the i-th sample, n represents a number of samples, X_{A} represents an average value of spectral reflectances of the samples in the waveband j, and Y_{A} represents an average value of the measured parameters of the respective samples in the waveband j.

In some embodiments, a modeling method in the step e5 is based on random forest, neural network, or a partial least square method.

FIGS. 2A-2J illustrate comparison diagrams of correlation coefficients before and after coupling of spectral information of multi-dimensions according to the disclosure. Specifically, curve graphs of spectral information before and after couplings of scales 1-10 (i.e., dimensions 1-10) and a determination coefficient (R2) of soil organic matter content are shown, in which the dotted line is a result after coupling and the solid line is a result before coupling. As seen from the figures that in the scales 1-3, the spectral information after coupling can significantly improve the sensitivity of spectrum to the soil organic matter content, and after coupling, wavebands of spectrum sensitive to the soil organic matter content increase significantly in number, and distribute uniformly in a range of 350-2500 nanometers (nm). In the scales 4-6, the spectral information after coupling can significantly improve a local sensitivity of spectrum to the soil organic matter content, and can make up for the lack of the local sensitivity of spectrum before coupling. In the scales 7-9, sensitivities of spectra to the soil organic matter content before and after coupling are not significantly enhanced or weakened. In the scale 10, the sensitivity of spectrum to the soil organic matter content after coupling is significantly higher than that before coupling.

FIG. 3 illustrates a comparative analysis diagram of modeling accuracy of an estimation model before and after coupling according to an embodiment of the disclosure, and FIG. 4 illustrates a comparative analysis diagram of verification accuracy before and after coupling according to an embodiment of the disclosure. As seen from FIG. 3 and FIG. 4 that, on the whole, the modelling accuracy and verification accuracy after coupling are significantly higher than that before coupling, which indicates that the coupling algorithms provided in the disclosure can significantly improve estimation capability of spectrum to soil organic matter content.

The above illustrative embodiments do not limit the shape, the material, the structure, etc. of the disclosure in any form. Any simple amendments, equivalent changes and modifications made to the above embodiments according to the technical essence of the disclosure should belong to the scope of protection of the technical solution of the disclosure.

Finally, it should be noted that the above embodiments are merely used to illustrate the technical solution of the disclosure, not to limit the disclosure. Although the disclosure has been described in detail with reference to the above embodiments, those of ordinary skill in the art should understand that the technical solution described in the above embodiments can still be modified, or some of technical features of the above embodiments can be equivalently substituted, but these modifications or substitutions do not make the essence of the corresponding technical solution deviate from the spirit and scope of the technical solution of the embodiments of the disclosure.

What is claimed is:

1. A spectral information separation and aggregation method, comprising:
step a1, performing smooth denoising on spectral data through a spectral denoising method to obtain processed spectral data, to thereby improve a signal-to-noise ratio of the spectral data and weaken interferences of noise information on separation and aggregation of spectral information;
step b2, for the processed spectral data obtained in the step a1, processing the processed spectral data through a spectral data processing method to obtain spectral information of at least two dimensions and thereby spectral information of multi-dimensions are obtained, and recording the spectral information of multi-dimensions as SIₙ;
step c3, for the spectral information of multi-dimensions obtained in the step b2, quantitatively analyzing correlations among spectral information of respective dimensions through a correlation-analysis algorithm, and calculating spectral information coupling coefficients of the respective dimensions according to the correlations among the spectral information of the respective dimensions;
step d4, based on the spectral information coupling coefficients of the respective dimensions obtained in the step c3, coupling the spectral information of multi-dimensions obtained in the step b2 through a coupling technology to obtain resultant spectral information; and
step e5, calculating a correlation between the resultant spectral information obtained in the step d4 and ground-object parameters through a correlation-analysis algorithm, and evaluating an effect of the coupling.

2. The spectral information separation and aggregation method as claimed in claim 1, wherein in the step a1, the spectral denoising method is used to perform smooth processing on the spectral data by a low-pass filter, and coefficients SM of the low-pass filter are as follows:
SM=[0.0800, 0.2147, 0.5400, 0.8653, 1.0000, 0.8653, 0.5400, 0.2147, 0.0800].

3. The spectral information separation and aggregation method as claimed in claim 2, wherein in the step b2, the spectral data processing method is one of a traditional mathematical transformation, a wavelet transformation and a spectral absorption feature algorithm.

4. The spectral information separation and aggregation method as claimed in claim 3, wherein in the step c3, the correlation-analysis algorithm is as follows:
$${cor}_{j} = \frac{{\sum }_{i = 1}^{n} ( {X}_{i} - {X}_{A} ) * ( {Y}_{i} - {Y}_{A} )}{\sqrt{{\sum }_{i = 1}^{n} ( {X}_{i} - {X}_{A} )} * \sqrt{{\sum }_{i = 1}^{n} ( {Y}_{i} - {Y}_{A} )}}$$
where, corⱼ represents a correlation coefficient, Xᵢ represents a spectral reflectance of an i-th sample in a waveband j, Yᵢ represents a measured parameter of the i-th sample, n represents a number of samples; X_{A} represents an average value of spectral reflectances of the samples in the waveband j, and Y_{A} represents an average value of the measured parameters of the respective samples in the waveband j;
a calculation method of the spectral information coupling coefficients is as follows:
$${cor}_{max \_ j} = max ( {cor}_{j} ) \\ {cor}_{max} = [ {cor}_{max \_ 1} , {cor}_{max \_ 2} , … , {cor}_{max \_ n} ] \\ {cor}_{max \_ all} = max ( {cor}_{max} ) \\ {coef}_{j} = \frac{{cor}_{max \_ j}}{{cor}_{max \_ all}}$$
where, cor_{max_j} represents one of a maximum correlation coefficient of a j-th transformation and a maximum correlation coefficient of a j-th scale based on wavelet decomposition; Corₘₐₓ represents a dataset constructed by the maximum correlation coefficients of respective transformations; Cor_{max_all} represents a maximum one of the maximum correlation coefficients of the respective transformations; coefⱼ represents a coupling coefficient of the j-th transformation; max represents solving a maximum value of a vector array.

5. The spectral information separation and aggregation method as claimed in claim 4, wherein in the step d4,
when the coupling is performed on the spectral information of multi-dimensions obtained by the wavelet transformation, one of the following (1) and (2) is carried out;
(1) after decomposition based on a same wavelet basis, a coupling formula of decomposed scale information is as follows:
$${S}_{c} = {\sum }_{n}^{1} {ST}_{j} * {coef}_{j}$$
where, S_{c} represents a coupling result of decomposed scale information after decomposition using the same wavelet basis, SW; represents decomposed j-th scale information, coefⱼ represents a coupling coefficient of the decomposed j-th scale information, and n represents a number of decomposition scales;
(2) after decomposition based on different wavelet bases, a coupling formula of decomposed scale information of each of the different wavelet bases is as follows:
$${S}_{wb \_ c} = {\sum }_{n}^{1} {SW}_{wb \_ j} * {coef}_{wb \_ j}$$
where, S_{wb_c} represents a coupling result of decomposed scale information after decomposition using a same wavelet basis wb of the different wavelet bases, SW_{wb_j} represents j-th scale information after decomposition using the wavelet basis wb, coef_{wb_j} represents a coupling coefficient of the j-th scale information after the decomposition using the wavelet basis wb, and n represents a number of decomposition scales,
$${S}_{c \_ all} = {\sum }_{m}^{1} {SW}_{wb \_ c} * {coef}_{wb \_ c}$$
where, S_{c_all} represents a coupling result of the different wavelet bases, SW_{wb_c} represents the coupling result of the decomposed scale information after decomposition using the wavelet basis wb, coef_{wb_c} represents a coupling coefficient of the coupling result of the decomposed scale information after decomposition using the wavelet basis wb, and m represents a number of the different wavelet bases;
when the coupling is performed on the spectral information of multi-dimensions obtained by one of the traditional mathematical transformation and the spectral absorption feature algorithm, each of methods used for processing of spectral data is required to obtain spectral information of one dimension, namely, a data amount of the spectral data after being processed through each of the methods does not increase, and a formula is used as follows:
$${S}_{c} = {\sum }_{n}^{1} {ST}_{i} * {coef}_{i}$$
where, S_{c} represents a coupling result after processing of spectral data through the methods, ST represents the spectral information obtained after processing of spectral data through an i-th method of the methods, coefᵢ represents a coupling coefficient of the spectral information obtained after processing of spectral data through the i-th method, and n represents a number of the methods.

6. The spectral information separation and aggregation method as claimed in claim 5, wherein in the step e5, the evaluating an effect of the coupling comprises:
performing preliminary evaluation on the effect of the coupling through a maximum value and an average value of correlation coefficients, and
performing a second evaluation on the effect of the coupling through maximum value and an average value of precision of an estimation model;
wherein the maximum values reflect an optimal effect, and the average values reflect an overall effect.

7. The spectral information separation and aggregation method as claimed in claim 6, wherein in the step e5,
for the coupling result of the spectral information obtained by the wavelet transformation, one of the following (1) and (2) is carried out;
(1) for the coupling result obtained by decomposition based on the same wavelet basis and then coupling, using a same wavelet basis to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
(2) for the coupling result obtained by decomposition based on the different wavelet bases, using the different wavelet bases to separate the coupling result and then performing evaluation using evaluation indicators, and during performing the evaluation using the evaluation indicators, one of an overall evaluation and a scale-by-scale evaluation is performed on the n number of decomposition scales to maintain consistency of evaluation objective;
for the coupling result of the spectral information processed by one of the traditional mathematical transformation and the spectral absorption feature algorithm, performing correlation-analysis directly with a detection object and performing evaluation using evaluation indicators, and the correlation-analysis algorithm used in the step e5 being as follows:
$${cor}_{j} = \frac{{\sum }_{i = 1}^{n} ( {X}_{i} - {X}_{A} ) * ( {Y}_{i} - {Y}_{A} )}{\sqrt{{\sum }_{i = 1}^{n} ( {X}_{i} - {X}_{A} )} * \sqrt{{\sum }_{i = 1}^{n} ( {Y}_{i} - {Y}_{A} )}}$$
where, corⱼ represents a correlation coefficient, Xᵢ represents a spectral reflectance of an i-th sample in a waveband j, Yᵢ represents a measured parameter of the i-th sample, n represents a number of samples, X_{A} represents an average value of spectral reflectances of the samples in the waveband j, and Y_{A} represents an average value of the measured parameters of the respective samples in the waveband j.

8. The spectral information separation and aggregation method as claimed in claim 7, wherein a modeling method in the step e5 is one of random forest, neural network, and a partial least-square method.
